(19) United States
(12) Patent Application Publication
(10) Pub. No.: US 2011/0048513 A1
(43) Pub. Date: Mar. 3, 2011

(54) ADHESIVE COMPOSITION AND METHOD FOR ATTACHING A COMPONENT TO A SUBSTRATE

(75) Inventors: Dennis Booth, Grass Lake, MI (US); Sharon Loomis, Jackson, MI (US); Beverly Zimmerman, Jackson, MI (US)

(73) Assignee: ADCO PRODUCTS, INC., Michigan Center, MI (US)

(21) Appl. No.: 12/935,811

(22) PCT Filed: Apr. 2, 2009
(86) PCT No.: PCT/US09/39312

§ 371 Date: Nov. 10, 2010

Related U.S. Application Data
(60) Provisional application No. 61/041,760, filed on Apr. 2, 2008.

(51) Int. Cl. H01L 31/042; C08L 15/00; C08K 3/26; C08K 3/34; C08K 3/22; C08K 5/09; C08K 5/08

(52) U.S. Cl. 136/252; 525/152; 524/518; 524/426; 524/451; 524/433; 524/291; 524/358

(57) ABSTRACT

A pressure sensitive adhesive composition for attaching a solar module to a substrate includes an uncured rubbery polymer blend, at least one of a tackifier or a curing agent blend, and a polybutene homopolymer. The tackifier includes a phenolic tackifier resin and the curing agent blend includes at least one of a cure accelerator, a sulfur activator, and a curing vulcanizing agent. The composition exhibits initial tackiness when uncured and high strength when cured. The composition is cured in situ on the substrate.

### CROSS-REFERENCE TO RELATED APPLICATIONS

This application claims the benefit of U.S. Provisional Application No. 61/041,760, filed on Apr. 2, 2008. The disclosure of the above application is incorporated herein by reference.

### FIELD

The present invention relates to an adhesive composition and method for attaching a component to a substrate, and more particularly to a pressure sensitive adhesive compound for attaching a component to a substrate that cures in place under normal heat cycles.

### BACKGROUND

The statements in this section merely provide background information related to the present disclosure and may or may not constitute prior art.

Various components including, but not limited to, photovoltaic solar modules, solar preassemblies, roofing membranes, repair or seam patches, and mechanical equipment or other components are regularly attached directly to roofing and other substrates. One common method of securing these various components to a roofing substrate includes using mechanical fasteners such as screws or bolts. However, these mechanical fasteners can be expensive and penetrate the substrate, which can lead to, for example, water invasion of a roof. When the substrate is a solar preassembly, for example, water invasion can damage the photovoltaic cells. Another mechanical fastening method involves the use of ballast to hold down the components. Ballast, however, can greatly increase the load on a roofing substrate.

An alternate method of securing a component to a roofing substrate includes the use of chemicals or other agents. For example, a hot melt adhesive (e.g., asphalt) may be employed that is liquid or nearly liquid at high temperatures but that hardens upon cooling. However, hot melt adhesives require the use of specialized equipment that must be transported to each jobsite. The roofing materials or components must be brought together while the adhesive is still hot for the two pieces to permanently adhere. A two component liquid that is mixed at the jobsite may also be employed. Two component liquids require the use of specialized equipment and are very dependent on ambient conditions for the hardening to take place in the proper timeframe in order to achieve proper application. Extruded tapes or profiles may be employed and offer advantages over hot melt or two component liquid systems. Tapes do not require specialized equipment at the jobsite, require less training of application personnel, and offer instantaneous adhesive properties. However, non-hardening tapes either do not flow around irregularities or do not develop the ultimate properties needed for long term durability. For example, acrylic, butyl rubber, halobutyl rubber, ethylene propylene rubber, EPDM rubber, natural rubber, and other known non-hardening systems do not provide the necessary properties required in roofing environments. One solution to provide an adhesive that provides initially soft properties transitioning to hard properties includes using encapsulated curing agents. Encapsulated curing agents require physical rupturing of the encapsulants during application of the roofing materials. This rupturing requires that a minimum physical stress level be applied to the tape to break the encapsulated curing agent. However, uneven application of stress during application will result in inconsistent properties in the adhesive, resulting in possible sporadic failures. These curing agents may also require the use of toxic chemicals such as isocyanates or peroxides.

Accordingly, there is a need in the art for a pressure sensitive adhesive operable to secure a component to a substrate. The pressure sensitive adhesive should be initially soft or tacky to promote initial adhesion, and be able to cure in place without additional steps to a hard condition. Moreover, the adhesive composition should meet weatherability and strength criteria, such as resistance to ultra-violet radiation exposure, freeze and thaw cycles, rain, snow, sleet, and hail exposure, wind uplift forces, and extremes in temperature.

### SUMMARY

The present invention provides a pressure sensitive adhesive composition and a method for attaching a component to a substrate. The composition includes an uncured rubbery polymer blend, at least one of a tackifier or a curing agent blend, and a polybutene homopolymer. The tackifier includes a phenolic tackifier resin and the curing agent blend includes at least one of a cure accelerator, a sulfur activator, and a curing vulcanizing agent. The composition exhibits initial tackiness when uncured and high strength when cured. The composition is cured in situ on the substrate.

In one embodiment, the uncured rubbery polymer blend is present in an amount from about 10% to about 60% by weight, the at least one tackifier is present in an amount from about 5% to about 25% by weight, the curing agent blend is present in an amount from about 1% to about 6% by weight, and the polybutene homopolymer is present in an amount from about 20% to about 60% by weight.

In another embodiment, the uncured rubbery polymer blend is present in an amount from about 10% to about 60% by weight, the curing agent blend is present in an amount from about 1% to about 6% by weight, and the polybutene homopolymer is present in an amount from about 20% to about 60% by weight.

In yet another embodiment, the uncured rubbery polymer blend is present in an amount from about 10% to about 60% by weight, the at least one tackifier is present in an amount from about 5% to about 25% by weight, and the polybutene homopolymer is present in an amount from about 20% to about 60% by weight.

In yet another embodiment, the two separate molecular weight polyisobutylenes comprise a first polyisobutylene having an average viscosity molecular weight of greater than approximately 100,000 and a second polyisobutylene having an average viscosity molecular weight less than approximately 100,000.

In yet another embodiment, the cure accelerator comprises tetramethylthiuram disulfide and benzothiazyl disulfide, the sulfur activator comprises zinc oxide, and the curing vulcanizing agent comprises sulfur.

In yet another embodiment, the pressure sensitive adhesive composition includes a plasticizer.

In yet another embodiment, the plasticizer comprises paraffinic process oil.

In yet another embodiment, the pressure sensitive adhesive composition includes at least one filler and rheology modifier.

In yet another embodiment, the filler and rheology modifier is selected from the group consisting of one or more of calcium carbonate, talc, and fumed silica.

In yet another embodiment, the pressure sensitive adhesive composition includes a desiccant.

In yet another embodiment, the desiccant comprises calcium oxide.

In yet another embodiment, the pressure sensitive adhesive composition includes an antioxidant.

In yet another embodiment, the antioxidant comprises tetrakismethylene(3,5-di-t-butyl-4-hydroxyhydro-cinnamate) methane.

In yet another embodiment, the pressure sensitive adhesive composition includes an ultra-violet radiation absorber.

In yet another embodiment, the ultra-violet radiation absorber comprises carbon black.

In yet another embodiment, the pressure sensitive adhesive composition includes a stabilizer.

In yet another embodiment, the stabilizer comprises tetrachloro-p-benzoquinone.

A further embodiment of the pressure sensitive adhesive composition includes an uncured rubbery polymer blend present in an amount from about 10% to about 60% by weight, at least one of a tackifier present in an amount from about 5% to about 25% by weight or a curing agent blend present in an amount from about 1% to about 5% by weight, the tackifier comprising a phenolic tackifier resin, the curing agent blend comprising at least one of a cure accelerator, a sulfur activator, and a curing vulcanizing agent, and a polybutene homopolymer present in an amount from about 20% to about 60% by weight.

In one embodiment, the pressure sensitive adhesive composition includes a plasticizer present in an amount from about 1% to about 5% by weight.

In yet another embodiment, the pressure sensitive adhesive composition includes at least one filler and rheology modifier present in an amount from about 1% to about 5% by weight.

In yet another embodiment, the pressure sensitive adhesive composition includes a desiccant present in an amount from about 2% to about 8% by weight.

In yet another embodiment, the pressure sensitive adhesive composition includes an antioxidant present in an amount from about 0.1% to about 0.5% by weight.

In yet another embodiment, the pressure sensitive adhesive composition includes carbon black present in an amount from about 2% to about 5% by weight.

In yet another embodiment, the pressure sensitive adhesive composition includes a stabilizer present in an amount from about 0.1% to about 0.5% by weight.

In yet another embodiment, the uncured rubbery polymer blend is selected from the group consisting of ethylene propylene norbornadiene terpolymer, ethylene propylene dicyclopentadiene terpolymer, ethylene propylene hexadiene terpolymer, chlorobutyl rubber, polyisobutylene, halogenated butyl rubber, and a halogenated copolymer of p-methylstyrene and isobutylene.

In yet another embodiment, the uncured rubbery polymer blend comprises ethylene propylene norbornadiene terpolymers or ethylene propylene dicyclopentadiene terpolymer present in an amount from about 1% to about 5% by weight, ethylene propylene hexadiene terpolymer present in an amount from about 2% to about 10% by weight, chlorobutyl rubber present in an amount from about 5% to about 25% by weight, and a first polyisobutylene present in an amount from about 2% to about 10% by weight.

In yet another embodiment, the first polyisobutylene has an average viscosity molecular weight of greater than approximately 100,000.

In yet another embodiment, the pressure sensitive adhesive composition includes a second polyisobutylene having an average viscosity molecular weight less than approximately 100,000 and present in an amount from about 0.1% to about 3% by weight.

In yet another embodiment, the pressure sensitive adhesive composition has a tensile strength from about 5 pounds per square inch (psi) to about 40 psi when uncured and has a tensile strength from about 50 psi to about 100 psi when cured.

An assembly for adhering to a substrate is also provided. The assembly includes a component having a bottom surface, an adhesive layer disposed on at least a portion of the bottom surface of the component, the adhesive layer having an uncured rubbery polymer blend present in an amount from about 10% to about 60% by weight, at least one of a tackifier present in an amount from about 5% to about 25% by weight or a curing agent blend present in an amount from about 1% to about 5% by weight, the tackifier comprising a phenolic tackifier resin, the curing agent blend comprising at least one of a cure accelerator, a sulfur activator, and a curing vulcanizing agent, and a polybutene homopolymer present in an amount from about 20% to about 60% by weight. A release liner is disposed overtop the adhesive layer and the release liner is removable from the adhesive layer. The adhesive layer cures after the adhesive layer has been attached to the substrate. The adhesive layer has a peel strength from about 20 pounds per square inch to about 30 pounds per square inch after 24 hours of being applied to the substrate at room temperature.

The pressure sensitive adhesive composition is uncured prior to application on the substrate and has a tensile strength from about 5 pounds per square inch (psi) to about 40 psi. Once in place, the composition cures and hardens under the normal thermal environment or solar heating of the substrate to a tensile strength from about 50 psi to about 100 psi.

Further areas of applicability will become apparent from the description provided herein. It should be understood that the description and specific examples and embodiments are intended for purposes of illustration only and are not intended to limit the scope of the present disclosure.

### DRAWINGS

FIG. 1 is a cross-sectional view of an embodiment of an adhesive layer according to the principles of the present invention located between an exemplary roofing substrate and an exemplary solar module; and

FIG. 2 is a cross-sectional view of an embodiment of a solar module having an adhesive layer according to the principles of the present invention.

### DETAILED DESCRIPTION

The following description is merely exemplary in nature and is not intended to limit the present disclosure, application, or uses.

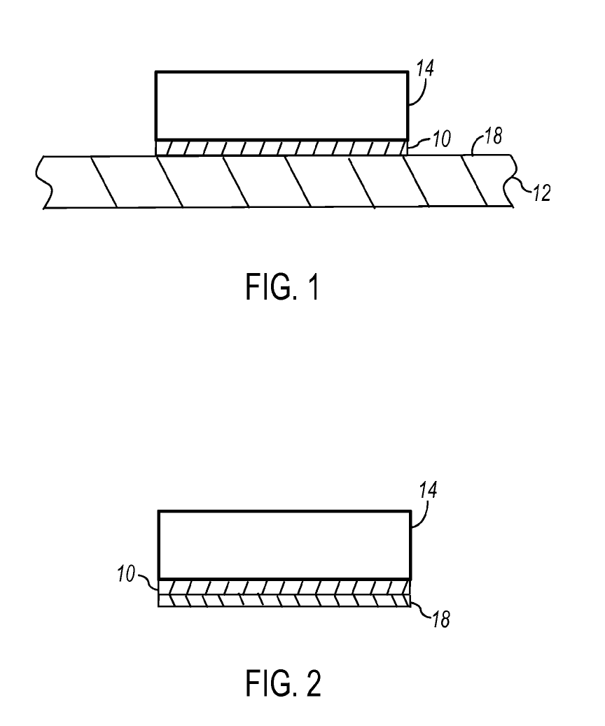

With reference to FIG. 1, an adhesive layer 10 according to the principles of the present invention is illustrated in use with an exemplary substrate 12 and an exemplary component 14. The substrate 12 is preferably a roof of a building, though other substrates may be employed without departing from the scope of the present invention, such as a backing sheet for receiving a plurality of photovoltaic cells. The substrate 12 may be comprised of various compositions, such as, for example, an ethylene propylene diene terpolymer (EPDM), a thermoplastic olefin (TPO), a polyvinyl chloride (PVC), a styrene-butadiene-styrene (SBS) modified bitumen, atactic polypropylene (APP) modified bitumen, galvanized steel, aluminum, stainless steel, and painted steel that includes polyvinylidene fluoride (PVDF), i.e. KYNAR™ coated steel. The substrate 12 includes an outer surface 16.

The component 14 may take various forms without departing from the scope of the present invention. For example, the component 14 may be a solar module that generally includes at least one photovoltaic cell (not shown) attached to a backing substrate (not shown). Exemplary photovoltaic cells for use with the present invention include, but are not limited to, thin film cells with a layer of cadmium telluride (Cd—Te), amorphous silicon, or copper-indium-diselenide (CuInSe₂) or crystalline silicon wafers embedded in a laminating film or gallium arsenide deposited on germanium or another substrate. The photovoltaic cell is operable to generate an electrical current from sunlight striking the photovoltaic cell. The backing substrate may be comprised of any number of materials selected for their strength and weatherability. Other examples of components 14 include, but are not limited to, solar preassemblies, roofing membranes and other roofing materials, repair or seam patches, and mechanical equipment or other mechanical components or devices.

Turning to FIG. 2, the adhesive layer 10 is preferably located on one side of the component 14. A release liner 18 covers the adhesive layer 10. The release liner 18 is operable to protect the adhesive layer 10 during transportation and handling of the component 14. The release liner 18 is operable to be removed from the adhesive layer 10 prior to attachment of the component 14 to the substrate 12.

With combined reference to FIGS. 1 and 2, a method of attaching the component 14 to the substrate 12 will now be described. First, the first release liner 18 is removed from the adhesive layer 10. Then, the component 14 is pressed or rolled onto the top surface 16 of the substrate 12. At this point, the adhesive layer 10 is uncured and therefore is sufficiently soft to “grab”, i.e. provide immediate adhesion, to the outer surface 16 of the substrate 12. In the uncured state, the adhesive layer has a tensile strength from about 5 psi to about 40 psi. This ability to quickly adhere to the outer surface 16 of the substrate 12 is especially useful when the substrate 12 is comprised of a material that is difficult to adhere to, such as, for example, granulated modified bitumen. The composition of the present invention will flow around irregularities and surface granules and become attached to the outer surface 16 of the substrate 12 beneath the granules. An adhesive that does not flow and make contact with the underlying bituminous surface will only provide adhesion to the granules. As these granules are only loosely adhered to the bituminous sheet and can be easily pulled from the surface, adequate adhesion may not be provided.

Once in place, the soft adhesive layer 10 is cured in place by heat from the normal environment of the substrate 12. More specifically, the composition polymers are vulcanized or crosslinked in order to harden the adhesive composition layer 10 in situ. As a cured, hardened composition, the adhesive layer 10 of the present invention exhibits greater shear properties and does not flow under the elevated temperatures that roofing materials experience. The hardened or cured adhesive layer 10 preferably has a tensile strength of about 50 psi to about 100 psi.

In an alternate embodiment, the adhesive layer 10 is fabricated in the form of an extruded tape wound in a roll on one or more of the release liners 18. The adhesive layer 10 is then applied to either the substrate 12 or the component 14. Then, the component 14 is pressed onto the substrate 12. The adhesive layer 10 then cures in place under the operating temperatures of the environment of the substrate 12, as described above.

As noted above, the adhesive layer 10 is soft and initially tacky, yet possesses high initial strength. Also, the composition of the adhesive layer 10 is able to adhere to the various kinds of substrates 12 and solar modules 14 described above while exhibiting necessary weatherability and strength criteria, such as resistance to ultra-violet radiation exposure, to freeze and thaw cycles, to rain, snow, sleet, and hail exposure, to wind uplift forces, and to extremes in temperature.

According to one aspect of the present invention, the adhesive layer 10 is comprised of a pressure sensitive adhesive composition that includes an uncured rubbery polymer blend and at least one of a tackifier and/or a curing agent blend. In one embodiment, the adhesive composition of the present invention includes an uncured rubbery polymer blend present in an amount from about 10% to about 60% by weight; at least one of a tackifier present in an amount from about 5% to about 25% by weight or a curing agent blend present in an amount from about 1% to about 5% by weight, and a polybutene homopolymer present in an amount from about 20% to about 60% by weight. The adhesive composition also preferably includes other components including plasticizers, water scavengers or desiccants, antioxidants, fillers and rheology modifiers, colorants and UV absorbers, and stabilizers.

The uncured rubbery polymer blend includes ethylene propylene norbornadiene or dicyclopentadiene terpolymer, ethylene propylene hexadiene terpolymer, chlorobutyl rubber, and two separate molecular weight polyisobutylenes. The polyisobutylenes preferably comprise a first polyisobutylene having an average viscosity molecular weight of greater than approximately 100,000 and a second polyisobutylene having an average viscosity molecular weight less than approximately 100,000. The uncured rubbery polymers impart strength and adhesion to the composition. Additionally, the chlorobutyl rubber acts as a crosslinking portion of the polymer blend during curing. Chemical derivatives and combinations of these uncured rubber polymers may also be used, for example, halogenated butyl rubber or a halogenated copolymer of p-methylstyrene and isobutylene.

The tackifiers preferably consist of polybutene homopolymer and phenolic tackifier resin. The polybutene homopolymer also acts as an adhesion promoter. Chemical derivatives and combinations of these tackifiers may also be employed in the composition without departing from the scope of the present invention.

The curing agent blend preferably consists of one or more of a cure accelerator, a sulfur activator, and a curing and vulcanizing agent. Exemplary cure accelerators include tetramethylthiuram disulfide and benzothiazyl disulfide. An exemplary sulfur activator includes zinc oxide. An exemplary curing and vulcanizing agent includes sulfur. Chemical derivatives and combinations of these cure accelerators, sulfur activators, and curing and vulcanizing agents may also be employed in the composition without departing from the scope of the present invention.

A suitable plasticizer for use in the present composition includes, but is not limited to, paraffinic process oil. Chemical derivatives and combinations of plasticizers may also be employed in the composition without departing from the scope of the present invention.

Suitable fillers and rheology modifiers for use in the present composition include, but are not limited to, one or more of calcium carbonate, talc, and fumed silica. Chemical derivatives and combinations of these fillers and rheology modifiers may also be employed in the composition without departing from the scope of the present invention.

A suitable water scavenger for use in the present composition includes, but is not limited to, calcium oxide. Chemical derivatives and combinations of calcium oxide may also be employed in the composition without departing from the scope of the present invention.

A suitable antioxidant for use in the present composition includes, but is not limited to, Tetrakismethylene(3,5-di-t-butyl-4-hydroxyhydro-cinnamate)methane. Chemical derivatives and combinations of compatible antioxidants may also be employed in the composition without departing from the scope of the present invention.

A suitable colorant and ultra-violet radiation absorber for use in the present composition includes, but is not limited to, carbon black. Chemical derivatives and combinations of compatible colorants and UV absorbers may also be employed in the composition without departing from the scope of the present invention.

A suitable stabilizer for use in the present composition includes, but is not limited to, Tetrachloro-p-benzoquinone. Chemical derivatives and combinations of compatible stabilizers may also be employed in the composition without departing from the scope of the present invention.

In order that the invention may be more readily understood, reference is made to the following example which is intended to illustrate the invention, but not limit the scope thereof:

| | | | Preferred | |
|---|---|---|---|---|
| | | | Composition | Exemplary |
| | | | Range | Composition |
| | Chemical Type | Function | Weight % | Weight % |
| 1 | Paraffinic Process Oil | Plasticizer | 1-5 | 1.51% |
| 2 | Calcium Carbonate | Filler, rheology adjustment | 1-5 | 2.50% |
| 3 | Calcium Oxide | Water scavenger | 2-8 | 4.95% |
| 4 | Tetrakismethylene (3,5-di-t-butyl-4-hydroxy- | Antioxidant | 0.1-0.5 | 0.30% |
| | hydrocinnamate) methane | | | |
| 5 | Polybutene Homopolymer | Tackifier, adhesion promoter | 20-60 | 40.66% |
| 6 | Talc | Filler, rheology modifier | 0-5 | 2.47% |
| 7 | Phenolic Tackifier Resin | Tackifier | 5-25* | 10.11% |
| 8 | Polyisobutylene | Polymer, imparts strength and | 0-10 | 4.35% |
| | | adhesion | | |
| 9 | Fumed Silica | Rheology modifier | 0-3 | 0.50% |
| 10 | Carbon Black | Colorant, UV absorber | 2-5 | 2.47% |
| 11 | Ethylene Propylene Norbornadiene or | Polymer, imparts strength and | 1-5 | 2.18% |
| | Dicyclopentadiene Terpolymer | adhesion | | |
| 12 | Ethylene Propylene Hexadiene Terpolymer | Polymer, imparts strength and | 2-10 | 8.67% |
| | | adhesion | | |
| 13 | Polyisobutylene | Polymer, imparts strength and | 2-10 | 4.95% |
| | | adhesion | | |
| 14 | Curing Agent Blend (Consisting of the following) | | 1.5-5* | 2.35% |
| | Tetramethylthiuram disulfide | Cure accelerator | 0-5 | 0.18% |
| | Benzothiazyl disulfide | Cure accelerator | 0-5 | 0.20% |
| | Zinc oxide | Sulfur activator | 0-5 | 1.27% |
| | Sulfur | Curing/vulcanizing agent | 0-5 | 0.34% |
| | Paraffinic Process Oil | Plasticizer in Curing Agent Blend | 0-5 | 0.36% |
| 15 | Tetrachloro-p-benzoquinone | Stabilizer | 0.1-0.5 | 0.15% |
| 16 | Chlorobutyl Rubber | Polymer, imparts strength and | 5-25 | 11.88% |
| | | adhesion, crosslinking portion of | | |
| | | polymer | | |
| | | | | 100.00% |

Exemplary Components by Trade Name:
1. Procoil 8240/Sunpar 2280
2. Armco 70
3. Mississippi Lime
4. BNX/Irganox 1010
5. H-300 Poly
6. Mistron
7. 29095 Durez, or another commercially available tackifier
8. SDG-8650
9. HiSil 233
10. Corax N-650
11. Trilene 65 or 67, or SDG-8650 Polyisobutylene
12. Nordel IP-4520
13. Efrolen P-85
14. BL/GRN Cure Blend
15. Vulklor
16. Exxpro 3433 or Lanxess 2030
*It is allowable that one of ingredients 7 or 14 be omitted as long as the other is present (non-zero).

The composition of the present invention was tested versus Sika 68. The results are summarized on the following chart:

| | | Peel strength | | Shear strength | |
|---|---|---|---|---|---|
| | | This | Sika | This | Sika |
| Conditioning, test conditions | Membranes | invention | 68 | invention | 68 |
| 24 hours at room temperature | PV-TPO | 24.8 | 4.8 | 4.9 | 4.3 |
| 24 hours at room temperature | PV-EPDM | 23.5 | 6.3 | 5.1 | 4.2 |
| 24 hours at room temperature | TPO-TPO | 24.9 | 14.4 | 5.3 | 4.6 |
| 24 hours at 190° F., pull at 190° F. | PV-TPO | 2.7 | 0.8 | 3.9 | 1.0 |
| 24 hours at 190° F., pull at 190° F. | PV-EPDM | 2.3 | 0.4 | 3.7 | 1.6 |
| 24 hours at 190° F., pull at 190° F. | TPO-TPO | 5.2 | 0.9 | 5.1 | 0.9 |
| 24 hours at 190° F., pull at room temperature | PV-TPO | 9.3 | 9.5 | 13.9 | 5.1 |
| 24 hours at 190° F., pull at room temperature | PV-EPDM | 14.8 | 8.0 | 13.1 | 3.5 |
| 24 hours at 190° F., pull at room temperature | TPO-TPO | 9.0 | 14.4 | 19.7 | 6.2 |

Units:
Peel Strength: Pounds per inch
Shear Strength: Pounds per square inch

The composition of the present invention exhibits a peel strength of at least 350 grams/cm at room temperature, at least 150 grams/cm at 70 degrees Celsius, and supports a static load of at least 23 grams/cm² at 70 degrees Celsius, preferably for a minimum of 96 hours. As noted above, the composition is initially uncured having a tensile strength from about 5 psi to about 40 psi. Full curing of the composition occurs after placement on the substrate 12. Full curing is achieved when further exposure to elevated temperatures do not change the adhesivity, strength, or static load resistance of the composition. The fully cured composition has a tensile strength of about 40 psi to about 100 psi. The compositions described above are blends of polymers that contribute to the proper balance of properties through its cure potential. Polyisobutylene rubber has no cure potential and thus acts as a polymer diluent. Ethylene propylene terpolymers have unsaturation levels as high as 10%.

The present invention maintains properties after ageing as required by Underwriter's Laboratories and IEC regulations.

The description of the invention is merely exemplary in nature and variations that do not depart from the gist of the invention are intended to be within the scope of the invention. Such variations are not to be regarded as a departure from the spirit and scope of the invention.

The following is claimed:

1. A pressure sensitive adhesive composition comprising:
an uncured rubbery polymer blend including ethylene propylene norbornadiene terpolymers or ethylene propylene dicyclopentadiene terpolymer, ethylene propylene hexadiene terpolymer, chlorobutyl rubber, and polyisobutylene;
at least one of a tackifier and a curing agent blend, wherein the tackifier includes a phenolic tackifier resin, and wherein the curing agent blend includes a cure accelerator, a sulfur activator, and a curing vulcanizing agent; and a polybutene homopolymer.

2. The pressure sensitive adhesive composition of claim 1 wherein the uncured rubbery polymer blend is present in an amount from about 10% to about 60% by weight, the at least one tackifier is present in an amount from about 5% to about 25% by weight, the curing agent blend is present in an amount from about 1% to about 6% by weight, and the polybutene homopolymer is present in an amount from about 20% to about 60% by weight.

3. The pressure sensitive adhesive composition of claim 1 wherein the uncured rubbery polymer blend is present in an amount from about 10% to about 60% by weight, the curing agent blend is present in an amount from about 1% to about 6% by weight, and the polybutene homopolymer is present in an amount from about 20% to about 60% by weight.

4. The pressure sensitive adhesive composition of claim 1 wherein the uncured rubbery polymer blend is present in an amount from about 10% to about 60% by weight, the at least one tackifier is present in an amount from about 5% to about 25% by weight, and the polybutene homopolymer is present in an amount from about 20% to about 60% by weight.

5. The pressure sensitive adhesive composition of claim 1 wherein the polyisobutylene has an average viscosity molecular weight of greater than approximately 100,000, and wherein the composition further comprises a polyisobutylene having an average viscosity molecular weight less than approximately 100,000.

6. The pressure sensitive adhesive composition of claim 1 wherein the cure accelerator comprises tetramethylthiuram disulfide and benzothiazyl disulfide, the sulfur activator comprises zinc oxide, and the curing vulcanizing agent comprises sulfur.

7. The pressure sensitive adhesive composition of claim 1 further comprising a plasticizer.

8. The pressure sensitive adhesive composition of claim 7 wherein the plasticizer comprises paraffinic process oil.

9. The pressure sensitive adhesive composition of claim 1 further comprising at least one filler and rheology modifier.

10. The pressure sensitive adhesive composition of claim 9 wherein the filler and rheology modifier is selected from the group consisting of one or more of calcium carbonate, talc, and fumed silica.

11. The pressure sensitive adhesive composition of claim 1 further comprising a desiccant.

12. The pressure sensitive adhesive composition of claim 11 wherein the desiccant comprises calcium oxide.

13. The pressure sensitive adhesive composition of claim 1 further comprising an antioxidant.

14. The pressure sensitive adhesive composition of claim 13 wherein the antioxidant comprises tetrakismethylene(3,5-di-t-butyl-4-hydroxyhydro-cinnamate) methane.

15. The pressure sensitive adhesive composition of claim 1 further comprising an ultra-violet radiation absorber.

16. The pressure sensitive adhesive composition of claim 15 wherein the ultra-violet radiation absorber comprises carbon black.

17. The pressure sensitive adhesive composition of claim 1 further comprising a stabilizer.

18. The pressure sensitive adhesive composition of claim 17 wherein the stabilizer comprises tetrachloro-p-benzoquinone.

19. A pressure sensitive adhesive composition comprising:
an uncured rubbery polymer blend present in an amount from about 10% to about 60% by weight;
at least one of a tackifier present in an amount from about 5% to about 25% by weight and a curing agent blend present in an amount from about 1% to about 5% by weight, wherein the tackifier includes a phenolic tackifier resin, and wherein the curing agent blend includes a cure accelerator, a sulfur activator, and a curing vulcanizing agent; and
a polybutene homopolymer present in an amount from about 20% to about 60% by weight.

20. The pressure sensitive adhesive composition of claim 19 wherein the cure accelerator comprises tetramethylthiuram disulfide and benzothiazyl disulfide, the sulfur activator comprises zinc oxide, and the curing vulcanizing agent comprises sulfur.

21. The pressure sensitive adhesive composition of claim 19 further comprising a plasticizer present in an amount from about 1% to about 5% by weight.

22. The pressure sensitive adhesive composition of claim 19 further comprising at least one filler and rheology modifier present in an amount from about 1% to about 5% by weight.

23. The pressure sensitive adhesive composition of claim 19 further comprising a desiccant present in an amount from about 2% to about 8% by weight.

24. The pressure sensitive adhesive composition of claim 19 further comprising an antioxidant present in an amount from about 0.1% to about 0.5% by weight.

25. The pressure sensitive adhesive composition of claim 19 further comprising carbon black present in an amount from about 2% to about 5% by weight.

26. The pressure sensitive adhesive composition of claim 19 further comprising a stabilizer present in an amount from about 0.1% to about 0.5% by weight.

27. The pressure sensitive adhesive composition of claim 19 wherein the uncured rubbery polymer blend is selected from the group consisting of ethylene propylene norbornadiene terpolymer, ethylene propylene dicyclopentadiene terpolymer, ethylene propylene hexadiene terpolymer, chlorobutyl rubber, polyisobutylene, halogenated butyl rubber, and a halogenated copolymer of p-methylstyrene and isobutylene.

28. The pressure sensitive adhesive composition of claim 19 wherein the uncured rubbery polymer blend comprises ethylene propylene norbornadiene terpolymers or ethylene propylene dicyclopentadiene terpolymer present in an amount from about 1% to about 5% by weight, ethylene propylene hexadiene terpolymer present in an amount from about 2% to about 10% by weight, chlorobutyl rubber present in an amount from about 5% to about 25% by weight, and a first polyisobutylene present in an amount from about 2% to about 10% by weight.

29. The pressure sensitive adhesive composition of claim 28 wherein the first polyisobutylene has an average viscosity molecular weight of greater than approximately 100,000.

30. The pressure sensitive adhesive composition of claim 30 further comprising a second polyisobutylene having an average viscosity molecular weight less than approximately 100,000 and present in an amount from about 0.1% to about 3% by weight.

31. The pressure sensitive adhesive composition of claim 19 wherein the pressure sensitive adhesive composition has a tensile strength from about 5 pounds per square inch (psi) to about 40 psi when uncured and has a tensile strength from about 50 psi to about 100 psi when cured.

32. A solar module assembly attachable to a substrate, the solar module assembly comprising:
a solar module having a bottom surface;
an adhesive layer having a first surface and a second surface, wherein the first surface is in contact with at least a portion of the bottom surface of the solar module, the adhesive layer comprising:
an uncured rubbery polymer blend present in an amount from about 10% to about 60% by weight;
at least one of a tackifier present in an amount from about 5% to about 25% by weight and a curing agent blend present in an amount from about 1% to about 5% by weight, wherein the tackifier includes a phenolic tackifier resin, and wherein the curing agent blend includes a cure accelerator, a sulfur activator, and a curing vulcanizing agent; and
a polybutene homopolymer present in an amount from about 20% to about 60% by weight; and
a release liner covering the second surface of the adhesive layer, wherein the release liner is removable from the adhesive layer, and
wherein the adhesive layer cures after the release liner has been removed to attach the solar module to the substrate.

33. The assembly of claim 32 wherein the adhesive layer has a peel strength from about 20 pounds per square inch to about 30 pounds per square inch after 24 hours of being applied to the substrate at room temperature.
